(19) United States
(12) Patent Application Publication
(10) Pub. No.: US 2025/0199078 A1
(43) Pub. Date: Jun. 19, 2025

(54) APPARATUS AND METHOD FOR INSPECTING BATTERY DEFECT BASED-ON CHARGING PROFILE

(71) Applicant: SK On Co., Ltd., Seoul (KR)

(72) Inventor: Seung Hoon JUNG, Daejeon (KR)

(21) Appl. No.: 18/977,933

(22) Filed: Dec. 12, 2024

(30) Foreign Application Priority Data
Dec. 19, 2023 (KR) 10-2023-0185607

(51) Int. Cl. G01R 31/374; G01R 31/3835; G01R 31/396; H01M 10/42

(52) U.S. Cl. CPC G01R 31/374; G01R 31/3835; G01R 31/396; H01M 10/4285

(57) ABSTRACT

An apparatus for inspecting a battery defect based on a charging profile, including a voltage detector generating a voltage profile including a detection voltage, detected during charging for a plurality of battery cells included in a tray; a temperature detector generating a temperature profile including a detection temperature detected during the charging; a first processing unit obtaining a voltage differentiation value based on the voltage profile; a second processing unit obtaining a temperature error value based on the temperature profile; and a defect determination unit determining a defective state or a normal state for the plurality of battery cells included in the tray, based on the voltage differentiation value and the temperature error value, is disclosed.

### CROSS-REFERENCE TO RELATED APPLICATION(S)

This patent document claims the priority and benefits of Korean Patent Application No. 10-2023-0185607 filed on Dec. 19, 2023, the disclosure of which is incorporated herein by reference in its entirety.

### TECHNICAL FIELD

The disclosure and implementations disclosed in this patent document generally relate to an apparatus and a method for inspecting a battery defect based on a charging profile.

### BACKGROUND

In general, in a formation process of applying electrical characteristics to a battery, when a short circuit occurs in a plurality of battery cells included in a tray due to internal damage such as folding of a separator or the like during a previous procedure, prior to packaging of a battery module, and the battery module including the plurality of battery cells is subsequently manufactured, there may be problems such as a decrease in yield of the battery module, a fire occurring in the battery module, or the like.

Accordingly, it may be necessary to properly inspect whether internal damage such as folding of a separator or the like has occurred in the plurality of battery cells included in the tray before manufacturing the battery module.

However, in the past, when internal damage has occurred in the plurality of battery cells included in the tray, a change in voltage may be too small to directly detect the change in voltage. Accordingly, it is difficult to directly detect a voltage change amount, and even when the voltage change amount is detected, there may be a problem that accuracy thereof is low.

### SUMMARY

An embodiment of the disclosure of this patent document is to provide an apparatus and a method for inspecting a battery defect based on a charging profile, may more accurately inspect a defective state of a plurality of battery cells included in a tray, based on a voltage differentiation value and a temperature error value, obtained based on a voltage profile and a temperature profile for each of the plurality of battery cells.

The technical problems of the disclosure of this patent document are not limited to those mentioned above, and other technical problems not mentioned will be clearly understood by those skilled in the art of the disclosure of this patent document from the description below.

An apparatus for inspecting a battery defect of the disclosure of this patent document may be widely applied to a transportation means such as an electric vehicle, a drone, or the like, a battery charging station, and other green technology fields such as a solar power generation, a wind power generation, or the like, using a battery. In addition, an apparatus for inspecting a battery defect of the disclosure of this patent document may be used in an eco-friendly electric vehicle, a hybrid vehicle, or the like to ameliorate the effects of climate change by reducing air pollution and greenhouse gas emissions.

In some embodiments of the disclosure of this patent document, an apparatus for inspecting a battery defect based on a charging profile, includes a voltage detector generating a voltage profile including a detection voltage, detected during charging for a plurality of battery cells included in a tray; a temperature detector generating a temperature profile including a detection temperature detected during the charging; a first processing unit obtaining a voltage differentiation value based on the voltage profile; a second processing unit obtaining a temperature error value based on the temperature profile; and a defect determination unit determining a defective state or a normal state of the plurality of battery cells included in the tray, based on the voltage differentiation value and the temperature error value.

In some embodiments of the disclosure of this patent document, a method for inspecting a battery defect based on a charging profile, includes a charging operation of performing charging of a plurality of battery cells included in a tray; a voltage detection operation of generating a voltage profile including a detection voltage, detected during the charging for the plurality of battery cells included in the tray; a temperature detection operation of generating a temperature profile including a detection temperature detected during the charging; a first processing operation of obtaining a voltage differentiation value based on the voltage profile; a second processing operation of obtaining a temperature error value based on the temperature profile; and a defect determination operation of determining a defective state or a normal state of the plurality of battery cells included in the tray, based on the voltage differentiation value and the temperature error value.

In addition, aspects of the disclosure of this patent document are not limited to the aspects mentioned above, and other aspects can be additionally understood in the process of the description below.

### BRIEF DESCRIPTION OF DRAWINGS

Certain aspects, features, and advantages of the disclosure of this patent document may be illustrated by the following detailed description with reference to the accompanying drawings.

FIG. 1 is a schematic diagram of an apparatus for inspecting a battery defect based on a charging profile according to an embodiment of the disclosure of this patent document.

FIG. 2 is an example diagram of an apparatus for inspecting a battery defect based on a charging profile according to an embodiment of the disclosure of this patent document.

FIG. 3 is an example diagram of a voltage profile obtained from a voltage detector.

FIG. 4 is an example diagram of a temperature profile obtained from a temperature detector.

FIG. 5 is an example diagram of a first processing unit.

FIG. 6 is an example diagram of a first processing unit.

FIG. 7 is an example diagram of a second processing unit.

FIG. 8 is an example diagram of a defect determination unit.

FIG. 9 is an example diagram of a condition-based state of a state determination unit.

FIG. 10 is an example diagram of a voltage profile.

FIG. 11 is an example diagram of a first differentiation value.

FIG. 12 is an example diagram of a second differentiation value.

FIG. 13 is a flowchart of a method for inspecting a battery defect, based on a charging profile according to an embodiment of the disclosure of this patent document.

FIG. 14 example diagram of a first is an differentiation value generation operation.

FIG. 15 is an example diagram of a second differentiation value generation operation.

FIG. 16 is an example diagram of a temperature error value generation operation.

FIG. 17 is an example diagram of a defect determination operation.

FIG. 18 is an example diagram of a state determination operation.

In the drawings and detailed description, the same reference numerals refer to the same components. The drawings may not be to scale, and relative sizes, proportions, and depictions of drawing elements may be exaggerated for clarity, explanation, and convenience.

### DETAILED DESCRIPTION

Hereinafter, embodiments of the disclosure of this patent document will be further described with reference to specific experimental examples. Inventive and comparative examples included in experimental examples are merely illustrative of the disclosure of this patent document and do not limit the scope of the appended claims. It will be apparent to those skilled in the art that various changes and modifications to the examples may be possible within the scope and technical idea of the disclosure of this patent document, and it may be natural that such changes and modifications fall within the scope of the appended claims.

Since the disclosure of this patent document may make various changes and have various embodiments, specific embodiments will be illustrated in the drawings and described in detail. However, this may not be intended to limit the disclosure of this patent document to specific embodiments, and should be understood to include all changes, equivalents, and substitutes included in the spirit and technical scope of the disclosure of this patent document.

Terms such as first, second, or the like may be used to describe various components, but the components should not be limited by the terms. The above terms may be used only for the purpose of distinguishing one component from another. For example, a first component may be named a second component, and similarly, the second component may also be named a first component without departing from the scope of the disclosure of this patent document. The term “and/or” may include any of a plurality of related stated items or a combination of a plurality of related stated items.

The terms used in the present application may be only used to describe specific embodiments, and may not be intended to limit the disclosure of this patent document. Singular expressions include plural expressions unless the context clearly otherwise. dictates In the present application, terms such as “include,” “comprise,” “have,” and the like may be intended to designate the presence of features, numbers, steps, operations, components, parts, or combinations thereof described in the specification, but may not be intended to indicate the presence of one or more other features. It should be understood that this does not exclude in advance possibility of existence or addition of elements, numbers, steps, operations, components, parts, or combinations thereof.

Unless otherwise defined, all terms used herein, including technical or scientific terms, have the same meaning as commonly understood by a person of ordinary skill in the technical field to which the disclosure of this patent document pertains. Terms defined in commonly used dictionaries should be interpreted as having a meaning consistent with the meaning in the context of the related technology, and should not be interpreted in an ideal or excessively formal sense unless explicitly defined in the present application.

Hereinafter, embodiments of the disclosure of this patent document will be described in more detail with reference to the attached drawings.

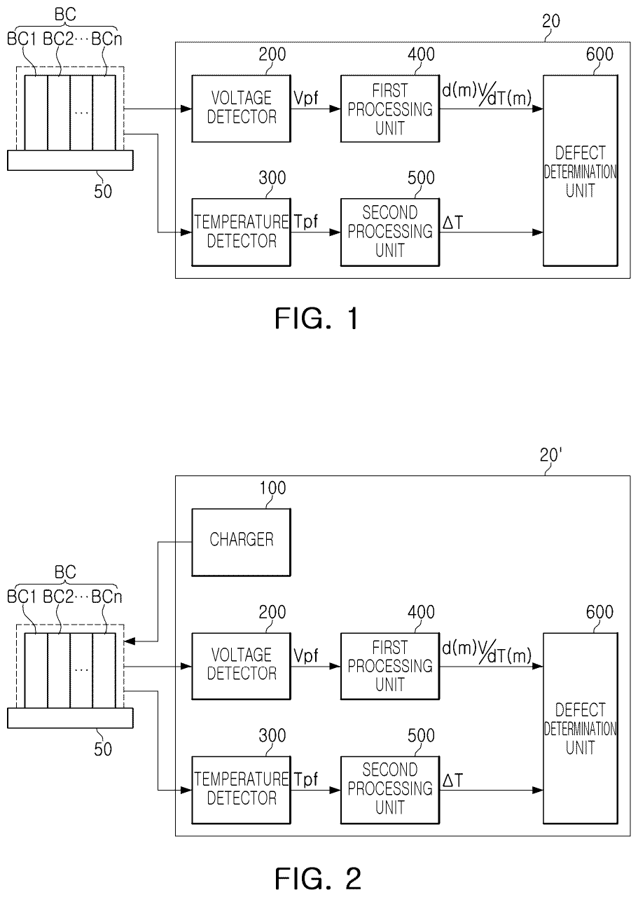

FIG. 1 is a schematic diagram of an apparatus for inspecting a battery defect based on a charging profile according to an embodiment of the disclosure of this patent document, and FIG. 2 is an example diagram of an apparatus for inspecting a battery defect based on a charging profile according to an embodiment of the disclosure of this patent document.

Referring to FIG. 1, an apparatus 20 for inspecting a battery defect based on a charging profile according to an embodiment of the disclosure of this patent document may include a voltage detector 200, a temperature detector 300, a first processing unit 400, a second processing unit 500, and a defect determination unit 600.

Referring to FIG. 2, an apparatus 20′ for inspecting a battery defect based on a charging profile according to an embodiment of the disclosure of this patent document may include a charger 100, a voltage detector 200, a temperature detector 300, a first processing unit 400, a second processing unit 500, and a defect determination unit 600.

Referring to FIG. 2, the charger 100 may perform charging for a plurality of battery cells BC (BC1 to BCn) included in the tray 50. For example, to obtain a charging profile for each of a plurality of battery cells included in a tray, the charger 100 may perform charging on each of the plurality of battery cells BC (BC1 to BCn).

Referring to FIGS. 1 and 2, the voltage detector 200 may generate a voltage profile Vpf including a detection voltage Vd detected over time during charging for each of the plurality of battery cells BC (BC1 to BCn) included in the tray 50.

The temperature detector 300 may generate a temperature profile Tpf including a detection temperature Td detected over time during the charging. For example, the temperature detector 300 may include a temperature sensor detecting a temperature of each of the plurality of battery cells BC (BC1 to BCn) included in the tray 50.

For example, when damage occurs in a battery cell to be inspected, a slight change in voltage may be included in the voltage profile Vpf, and a change in temperature may be included in the temperature profile Tpf. It can be seen that the damage occurrence in the battery cell may be detected based on the voltage profile Vpf and the temperature profile Tpf.

The first processing unit 400 may obtain a voltage differentiation value d(m)V/dT(m) (m=1 or 2) based on the voltage profile Vpf.

For example, in a case in which there is internal damage in the battery cell to be inspected, to accurately detect a minute change in voltage included in the voltage profile Vpf, the disclosure of this patent document may perform differentiation on a voltage of the voltage profile Vpf to represent the minute change in voltage to a large degree. For example, differentiation on a voltage may be a change in voltage (V2−V1) for a pre-set time interval (T2−T1), and the time interval (T2−T1) may be a specific time (e.g., 2 seconds) within a time range exceeding 0 seconds and less than or equal to 10 seconds. This will be described with reference to FIGS. 10, 11, and 12.

The second processing unit 500 may obtain a temperature error value ΔT based on the temperature profile Tpf. For example, a temperature error value ΔT may be a change in temperature for a preset time, and the preset time may be an arbitrarily set time' within 10 seconds, for example, 2 seconds, but the disclosure of this patent document is not limited thereto.

The defect determination unit 600 may determine a defective state or a normal state for the plurality of battery cells BC (BC1 to BCn) included in the tray 50, based on the voltage differentiation value d(m)V/dT(m) and the temperature error value ΔT. For example, in the voltage differentiation value d(m)V/dT(m), d(1)V/dT(1) (when m=1) may be a first voltage differentiation value dV/dT for a detection voltage of the battery cell included in the voltage profile Vpf, and d(2)V/dT(2) (when m=2) may be a second voltage differentiation value d2V/dT2.

In the disclosure of this patent document, the charger 100, the voltage detector 200, the temperature detector 300, the first processing unit 400, the second processing unit 500, and the defect determination unit 600 may be implemented as hardware or software in at least one integrated circuit (IC) built into the apparatus 20′, respectively, and are not particularly limited to any one.

In addition, the charger 100, the voltage detector 200, the temperature detector 300, the first processing unit 400, the second processing unit 500, and the defect determination unit 600 may be implemented as individual processors, or may be implemented as one processor, respectively, and are not particularly limited to any one.

For each drawing of the disclosure of this patent document, unnecessary redundant descriptions of components with the same symbols and the same functions will be omitted, and possible differences between the drawings will be explained.

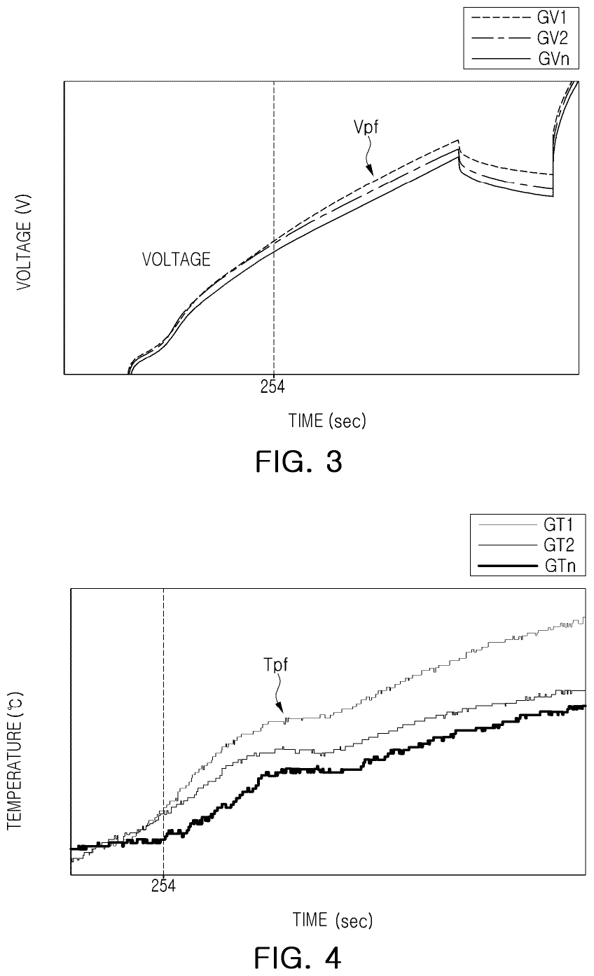

FIG. 3 is an example diagram of a voltage profile obtained from a voltage detector, and FIG. 4 is an example diagram of a temperature profile obtained from a temperature detector.

Referring to FIG. 3, when a plurality of first, second to nth battery cells (BC1, BC2 to BCn of FIG. 2) are included in a tray 50, GV1 may be a first voltage profile for a first battery cell (BC1 of FIG. 2) among the first, second to nth battery cells (BC1, BC2 to BCn of FIG. 2), GV2 may be a second voltage profile for a second battery cell (BC2 of FIG. 2) among the first, second to n^{th} battery cells, and GVn may be an nth voltage profile for an n^{th} battery cell (BCn of FIG. 2) among the first, second to n^{th} battery cells. Referring to GV1 of FIG. 3, it can be seen that an abnormal increase in detection voltage of a battery cell, corresponding thereto, is confirmed from a specific time (e.g., 254 sec).

Referring to FIG. 4, GT1 may be a first temperature profile for a first battery cell (BC1 of FIG. 2), GT2 may be a second temperature profile for a second battery cell (BC2 of FIG. 2), and GTn may be an n^{th} temperature profile for an n^{th} battery cell (BCn of FIG. 2). Referring to GT1 of FIG. 4, it can be seen that an abnormal increase in detection temperature of a battery cell, corresponding thereto, is confirmed from the same specific time (e.g., 254 sec) at which a voltage increases.

Hereinafter, in the disclosure of this patent document, among a plurality of first, second, and nth battery cells included in a tray, a single battery cell (e.g., BC1) may be described, but such examples may be for convenience of explanation and understanding, and the disclosure of this patent document is not limited to such examples.

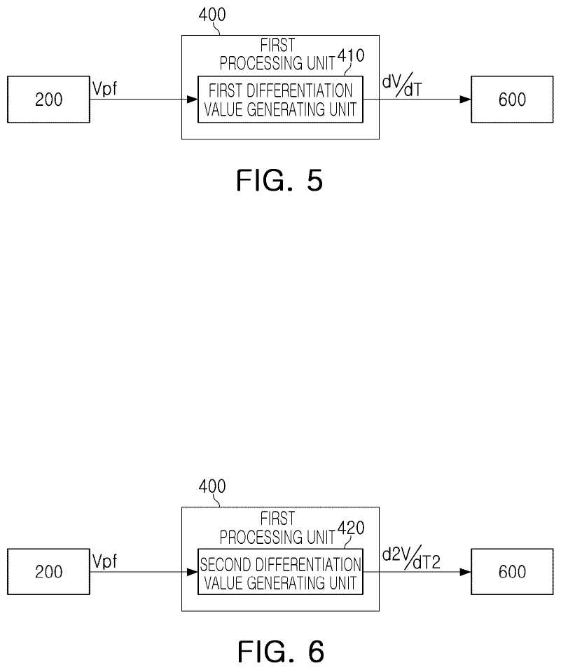

FIG. 5 is an example diagram of a first processing unit, and FIG. 6 is an example diagram of a first processing unit.

Referring to FIG. 5, a first processing unit 400 may include a first differentiation value generating unit 410. For example, a first differentiation value generating unit 410 may generate a first voltage differentiation value dV/dT based on a voltage profile Vpf for each of first to n^{th} battery cells BC (BC1 to BCn) included in a tray 50.

Referring to FIG. 6, a first processing unit 400 may include a second differentiation value generating unit 420. For example, a second differentiation value generating unit 420 may generate a second voltage differentiation value d2V/dT2 based on a voltage profile Vpf for each of first to nth battery cells BC (BC1 to BCn) included in a tray 50.

Referring to FIGS. 5 and 6, the first processing unit 400 may include any one of the first differentiation value generating unit 410 or the second differentiation value generating unit 420, and may thus generate any one of the first voltage differentiation value dV/dT or the second voltage differentiation value d2V/dT2.

The voltage profile Vpf, the first differentiation value dV/dT and the second differentiation value d2V/dT2 will be described later with reference to FIGS. 10, 11 and 12.

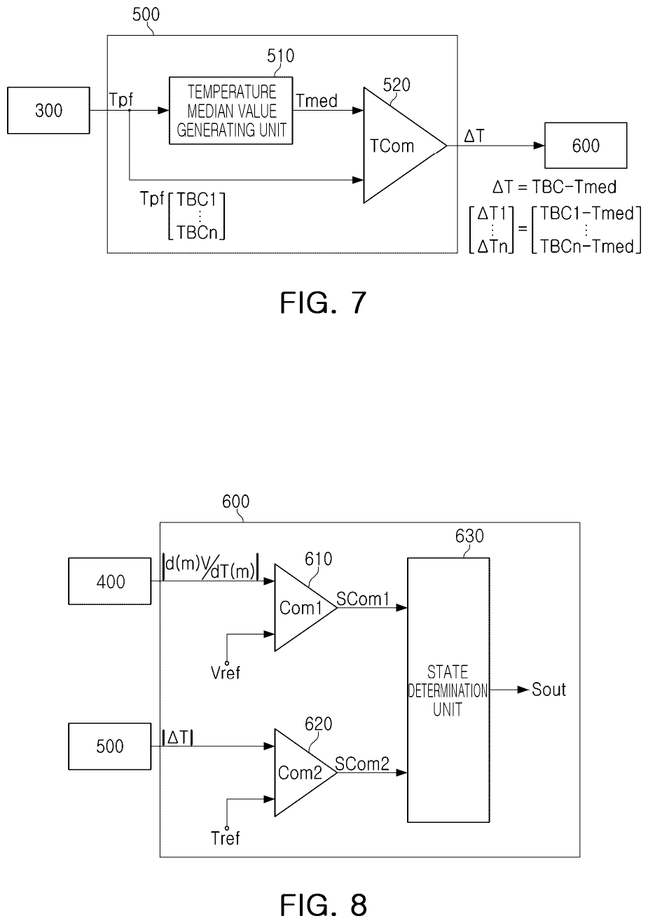

FIG. 7 is an example diagram of a second processing unit.

Referring to FIG. 7, a second processing unit 500 may include a temperature median value generating unit 510 and a temperature comparison unit 520 (TCom).

The temperature median value generating unit 510 may generate a temperature median value Tmed of first to n^{th} battery cells BC (BC1 to BCn) at a preset time, based on the temperature profile Tpf for each of the first to nth battery cells BC (BC1 to BCn) included in a tray 50. For example, when, in the temperature profile Tpf, a minimum value thereof is 40 degrees and a maximum value thereof is 50 degrees, a temperature median value thereof may be 45 degrees.

The temperature comparison unit 520 (TCom) may generate first to n^{th} temperature error values ΔT (ΔT1 to ΔTn) using first to n^{th} temperature values TBC1 to TBCn of the first to n^{th} battery cells BC (BC1 to BCn) and the temperature median value Tmed therebetween.

FIG. 8 is an example diagram of a defect determination unit.

Referring to FIG. 8, a defect determination unit 600 may include a first comparison unit 610 (Com1), a second comparison unit 620 (Com2), and a state determination unit 630.

The first comparison unit 610 may compare whether a voltage differentiation value d(m)V/dT(m) is within a range of a voltage reference Vref, and may output a first comparison signal Scom1.

For example, a voltage differentiation value d(m)V/dT(m) may be an absolute value |d(m)V/dT(m))| of the voltage differentiation value d(m)V/dT(m), and the first comparison unit 610 may determine whether the absolute value |d(m)V/dT(m))| of the voltage differentiation value d(m)V/dT(m) is less or greater than the voltage reference Vref. When the voltage differentiation value d(m V/dT(m) is not the absolute value |d(m)V/dT(m))| of the voltage differentiation value d(m)V/dT(m), the first comparison unit 610 may determine whether the voltage differentiation value d(m)V/dT(m) is included inside or outside of a range (−Vref to+Vref) of the voltage reference Vref.

For example, the first comparison unit 610 may output the first comparison signal Scom1 of a low level (logic “0”) when the absolute value |d(m)V/dT(m))| of the voltage differentiation value d(m)V/dT(m) is less than the voltage reference Vref, and may output the first comparison signal Scom1 of a high level (logic “1”) when the absolute value |d(m)V/dT(m))| of the voltage differentiation value d(m)V/dT(m) is greater than or equal to the voltage reference Vref.

The second comparison unit 620 may compare whether a temperature error value ΔT is within a range of a temperature reference Tref, and may output a second comparison signal Scom2.

For example, a temperature error value ΔT may be an absolute value |ΔT| of the temperature error value ΔT, and the second comparison unit 620 may determine whether the absolute value |ΔT| of the temperature error value ΔT may be less or greater than the temperature reference Tref. When the temperature error value ΔT is not the absolute value |ΔT| of the temperature error value ΔT, the second comparison unit 620 may determine whether the temperature error value ΔT is included inside or outside of a range (−Tref to+Tref) of the temperature reference Tref.

For example, the second comparison unit 620 may output the second comparison signal Scom2 of a low level (logic “0”) when the absolute value |ΔT| of the temperature error value ΔT is less than the temperature reference Tref, and may output the second comparison signal Scom2 of a high level (logic “1”) when the absolute value |ΔT| of the temperature error value ΔT is greater than or equal to the temperature reference Tref.

The state determination unit 630 may determine a defective state or a normal state for first to n^{th} battery cells BC (BC1 to BCn) included in a tray 50, based on the first comparison signal Scom1 and the second comparison signal Scom2.

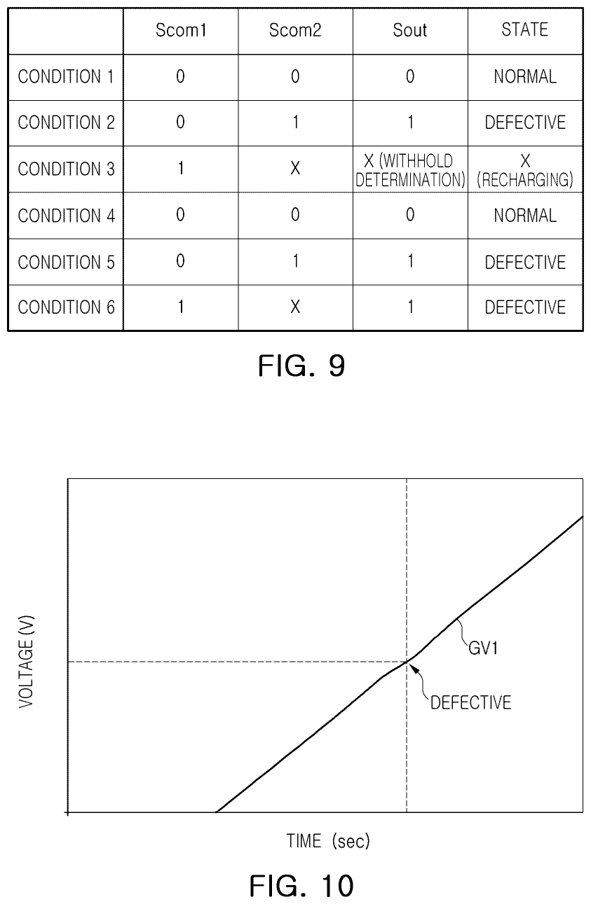

For example, the state determination unit 630 may determine a state of each of the first to n^{th} battery cells BC (BC1 to BCn) as a defective state or a normal state, according to a plurality of conditions determined according to a level of the first comparison signal Scom1 and a level of the second comparison signal Scom2, may output an output signal Sout including a determination result thereof, and may determine the same with reference to FIG. 9.

FIG. 9 is an example diagram of a condition-based state of a state determination unit.

Referring to FIG. 9, a defect determination unit 600 may determine states respectively corresponding to condition 1, condition 2, condition 3, condition 4, condition 5, and condition 6, for example, according to a first comparison signal Scom1 and a second comparison signal Scom2.

First, regarding condition 1, the defect determination unit 600 may determine that a voltage differentiation value d(m)V/dT(m) is within a range of a voltage reference when the first comparison signal Scom1 is at a low level (logic “0”), for example, and may determine that a temperature error value ΔT is within a range of a temperature reference when the second comparison signal Scom2 is at a low level (logic “0”).

In this case, states of first to n^{th} battery cells BC (BC1 to BCn) included in a tray 50 may be determined as a normal state, and therefore, an output signal Sout of a low level may be output.

Next, regarding condition 2, the defect determination unit 600 may determine that the voltage differentiation value d(m)V/dT(m) is within the range of the voltage reference when the first comparison signal Scom1 is at a low level (logic “0”), for example, and may determine that temperature error value ΔT is out of the range of the temperature reference when the second comparison signal Scom2 is at a high level (logic “1”).

In this case, the states of the first to nth battery cells BC (BC1 to BCn) included in the tray 50 may be determined as a defective state, and therefore, an output signal Sout of a high level may be output.

Next, regarding condition 3, the defect determination unit 600 may determine that the voltage differentiation value d(m)V/dT(m) is out of the range of the voltage reference, for example, when the first comparison signal Scom1 is at a high level (logic “1”), and in this case, it can be recognized that there is possibility of defectiveness regardless of the state of the second comparison signal Scom2, and may proceed with recharging through a charger 100.

In this case, the defect determination unit 600 may re-determine defective states or normal states for the plurality of battery cells included in the tray, based on the first comparison signal and the second comparison signal, after the recharging through the charger 100.

After the recharging is performed by the charger 100 for the first to nth battery cells BC (BC1 to BCn) included in the tray 50, the defect determination unit 600 may re-output the first comparison signal Scom1 through a first comparison unit 610, based on a voltage profile Vpf for each of the first to n^{th} battery cells BC (BC1 to BCn) included in the tray 50. In addition, the second comparison signal Scom2 may be re-output through a second comparison unit 620, based on a temperature profile Tpf for each of the first to n^{th} battery cells BC (BC1 to BCn) included in the tray 50.

Then, conditions 4, 5, and 6 will be described.

After the recharging, regarding condition 4, the defect determination unit 600 may determine that the voltage differentiation value d(m)V/dT(m) is within the range of the voltage reference, for example, when the first comparison signal Scom1 is at a low level (logic “0”), and may determine that the temperature error value ΔT is within the range of the temperature reference when the second comparison signal Scom2 is at a low level (logic “0”).

In this case, the states of the first to n^{th} battery cells BC (BC1 to BCn) included in the tray 50 may be determined as a normal state, and therefore, an output signal Sout of a low level may be output.

Next, regarding condition 5, the defect determination unit 600 may determine that the voltage differentiation value d(m)V/dT(m) is within the range of the voltage reference when the first comparison signal Scom1 is at a low level (logic “0”), for example, and may determine that the temperature error value ΔT is out of the range of the temperature reference when the second comparison signal Scom2 is at a high level (logic “1”).

In this case, the states of the first to n^{th} battery cells BC (BC1 to BCn) included in the tray 50 may be determined as a defective state, and therefore, an output signal Sout of a high level may be output.

Next, regarding condition 6, the defect determination unit 600 may determine a defective state regardless of the state of the second comparison signal Scom2, for example, when the first comparison signal Scom1 is at a low level (logic “1”), and therefore, may output an output signal Sout of a high level.

In the disclosure of this patent document, the high level and the low level will be explained as examples of logic high <1> and logic low <0>, respectively, but may be for the convenience of explanation and understanding, and are not limited thereto.

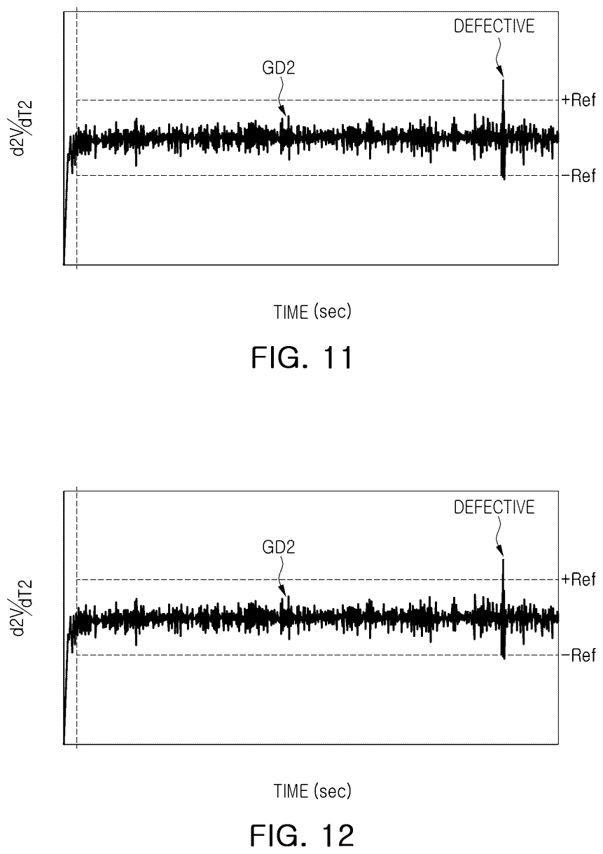

FIG. 10 is an example diagram of a voltage profile, and FIG. 11 is an example diagram of a first differentiation value. FIG. 12 is an example diagram of a second differentiation value.

Referring to FIG. 10, GV1 may be a voltage profile, and a portion indicated as defective may be a portion in which a voltage of a battery cell, corresponding thereto, changes slightly due to an internal defect of the battery cell. Since it is not easy to detect a minute change in voltage, a voltage included in a voltage profile may be differentiated to obtain a first differentiation value dV/dT or a second differentiation value d2V/dT2, and the first differentiation value dV/dT or the second differentiation value d2V/dT2 may be used as basic information for determining the internal defect of the battery cell.

Referring to FIG. 11, GD1 may be a graph of a first differentiation value dV/dT, and a portion indicated as defective in GD1 may be a portion in which a voltage changes due to an internal defect of a battery cell. In this manner, the first differentiation value dV/dT may be used to detect the portion in which the voltage changes, as compared to a preset reference value.

Referring to FIG. 12, GD2 may be a graph of a second differentiation value d2V/dT2, and a portion indicated as defective in GD2 may be a portion in which a voltage changes due to an internal defect of a battery cell. In this manner, the second derivative value d2V/dT2 may be used to detect the portion in which the voltage changes, as compared to a preset reference value (+Ref or −Ref) (e.g., +Ref: −1 to 0 mV, or −Ref: 0 to 1 mV).

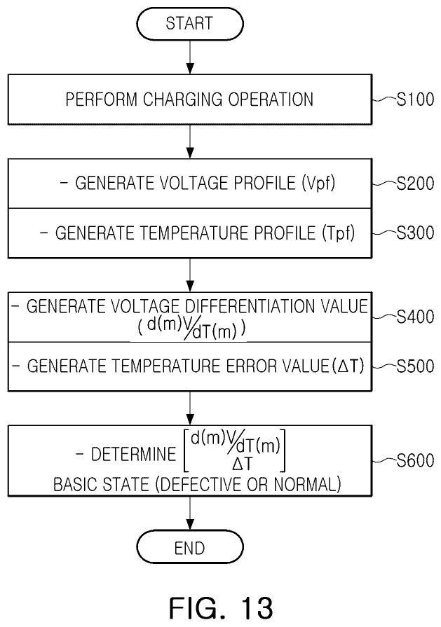

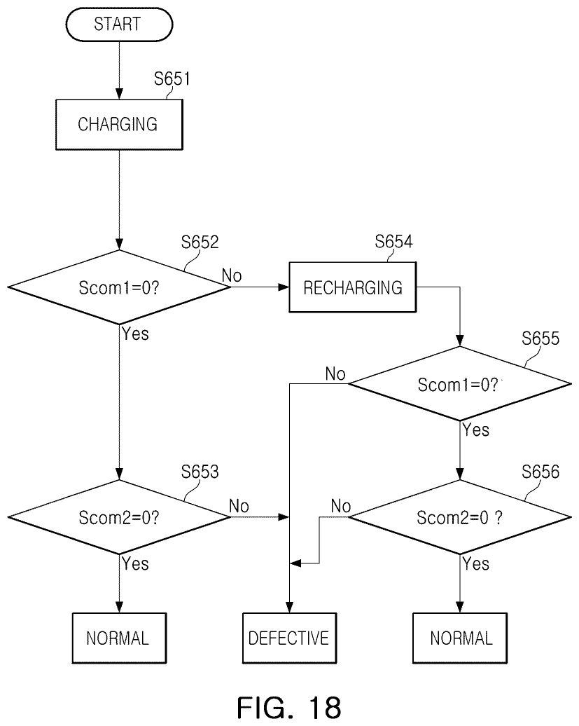

Hereinafter, with reference to FIGS. 13 and 18, a method for inspecting a battery defect based on a charging profile will be described. In the disclosure of this patent document, description of the method based on a charging profile and description of the apparatus based on a charging profile may be applied complementarily or commonly, unless they are mutually exclusive.

FIG. 13 is a flowchart of a method for inspecting a battery defect, based on a charging profile according to an embodiment of the disclosure of this patent document.

With reference to FIGS. 1 and 13, a method for inspecting a battery defect based on a charging profile, according to an embodiment of the disclosure of this patent document, may include a charging operation (S100), a voltage detection operation (S200), a temperature detection operation (S300), a first processing operation (S400), a second processing operation (S500), and a defect determination operation (S600).

In the charging operation (S100), an apparatus 20′ for inspecting a battery defect based on a charging profile, as in FIG. 2, may perform charging for first to nth battery cells BC (BC1 to BCn) included in a tray 50.

In the voltage detection operation (S200), the apparatus 20′, as in FIG. 2, may generate a voltage profile Vpf including a detection voltage Vd detected during the charging for the first to n^{th} battery cells BC (BC1 to BCn) included in the tray 50.

In the temperature detection operation (S300), the apparatus 20′, as in FIG. 2, may generate a temperature profile Tpf including a detection temperature Td detected during the charging.

In the first processing operation (S400), the apparatus 20′, as in FIG. 2, may obtain a voltage differentiation value d(m)V/dT(m) (m=1 or 2) based on the voltage profile Vpf.

In the second processing operation (S500), the apparatus 20′, as in FIG. 2, may obtain a temperature error value ΔT based on the temperature profile Tpf.

In the defect determination operation (S600), the apparatus 20′, as in FIG. 2, may determine a defective state or a normal state for the first to nth battery cells BC (BC1 to BCn) included in the tray 50, based on the voltage differentiation value d(m)V/dT(m) and the temperature error value ΔT.

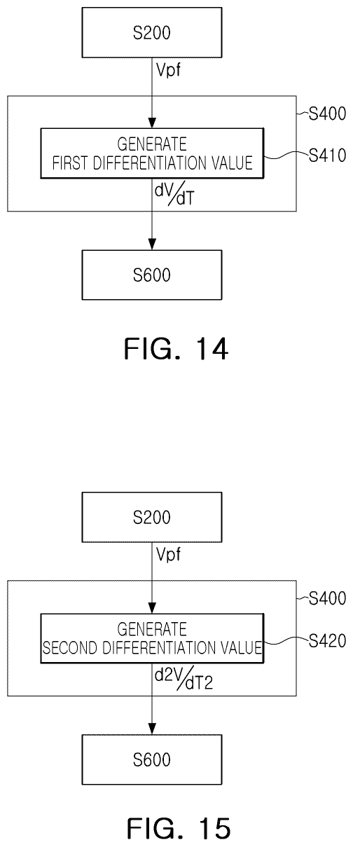

FIG. 14 is an example diagram of a first differentiation value generation operation, and FIG. 15 is an example diagram of a second differentiation value generation operation.

Referring to FIG. 14, a first processing operation (S400) may include a first differentiation value generation operation (S410).

In the first differentiation value generation operation (S410), an apparatus 20′ for inspecting a battery defect based on a charging profile, as in FIG. 2, may generate a first voltage differentiation value dV/dT based on a voltage profile Vpf for each of first to n^{th} battery cells BC (BC1 to BCn) included in a tray 50.

Referring to FIG. 15, a first processing operation (S400) may include a second differentiation value generation operation (S420).

In the second differentiation value generation operation (S420), an apparatus 20′ for inspecting a battery defect based on a charging profile, as in FIG. 2, may generate a second voltage differentiation value d2V/dT2 based on a voltage profile Vpf for each of first to n^{th} battery cells BC (BC1 to BCn) included in a tray 50.

Referring to FIG. 14 and FIG. 15, the first processing operation (S400) may include any one of the first differentiation value generation operation (S410) or the second differentiation value generation operation (S420), and thus may generate at least one of the first voltage differentiation value dV/dT or the second voltage differentiation value d2V/dT2.

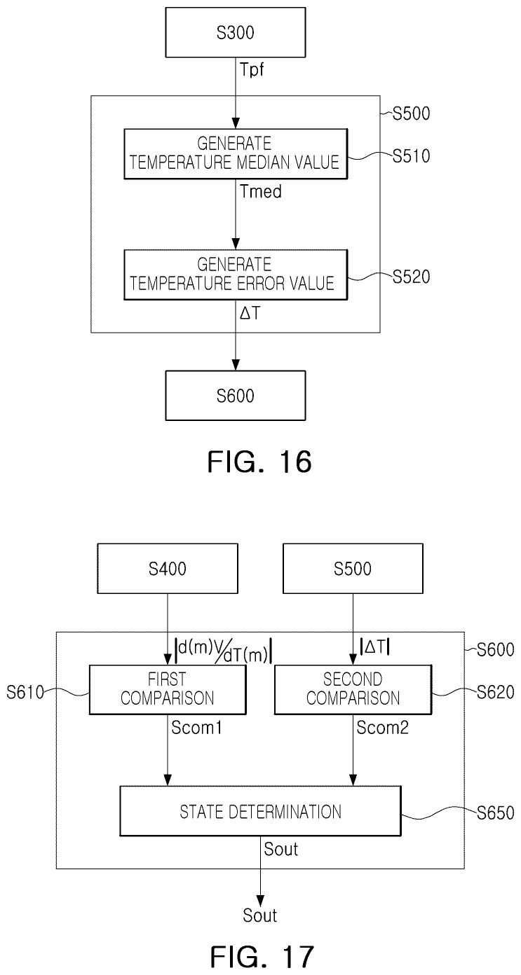

FIG. 16 is an example diagram of a temperature error value generation operation.

Referring to FIG. 16, a second processing operation (S500) may include a temperature comparison operation (S510) (TCom).

In the temperature comparison operation (S510) (TCom), an apparatus 20′ for inspecting a battery defect based on a charging profile, as in FIG. 2, may generate, based on a temperature profile Tpf for each of first to nth battery cells BC (BC1 to BCn), a temperature error value ΔT (ΔT1 to ΔTn) between a temperature median value Tmed of a plurality of battery cells BC (BC1 to BCn) and a temperature value (TBC1 to TBCn) of each of the battery cells BC (BC1 to BCn) at a preset point in time.

FIG. 17 is an example diagram of a defect determination operation.

Referring to FIG. 17, a defect determination operation (S600) may include a first comparison operation (S610), a second comparison operation (S620), and a state determination operation (S630).

In the first comparison operation (S610), an apparatus 20′ for inspecting a battery defect based on a charging profile, as in FIG. 2, may compare whether a voltage differentiation value d(m)V/dT(m) (e.g., an absolute value (|d(m)V/dT(m)|) of the voltage differentiation value d(m)V/dT(m)) is within a range of a voltage reference Vref, and may output a first comparison signal Scom1.

In the second comparison operation (S620), the apparatus 20′, as in FIG. 2, may compare whether an absolute value |ΔT| of a temperature error value ΔT is within a range of a temperature reference Tref (e.g., ±1° C.), and may output a second comparison signal Scom2.

In the state determination operation (S630), the apparatus 20′, as in FIG. 2, may determine a defective state or a normal state for each of first to nth battery cells BC (BC1 to BCn) included in a tray 50, based on the first comparison signal Scom1 and the second comparison signal Scom2, and therefore, for a battery cell to be inspected, corresponding thereto, among the first to nth battery cells BC (BC1 to BCn) included in the tray 50, when it is in a normal state, an output signal Sout having a low level may be output, and when it is in a defective state, an output signal Sout having a high level may be output.

FIG. 18 is an example diagram of a state determination operation.

With reference to FIG. 18, operations for condition 1, condition 2, condition 3, condition 4, condition 5, and condition 6 (see FIG. 9) performed in a defect determination operation (S600) will be described.

In the defect determination operation (S600), an apparatus 20′ for inspecting a battery defect based on a charging profile, as in FIG. 2, may output a first comparison signal Scom1 and a second comparison signal Scom2 through a process, as described above, after performing charging of each of first to nth battery cells BC (BC1 to BCn) included in a tray 50 (see S651).

First, regarding condition 1, after a battery is charged (see S651), when a first comparison signal Scom1 is at a low level (logic “0”) (see S652), a voltage differentiation value d(m)V/dT(m) may be determined as being within a range of a voltage reference, and when a second comparison signal Scom2 is at a low level (logic “0”) (see S653), a temperature error value ΔT may be determined as being within a range of a temperature reference.

In this case (corresponding to condition 1 of FIG. 9), states of the first to nth battery cells BC (BC1 to BCn) included in the tray 50 may be determined as a normal state.

Next, regarding condition 2, in the defect determination operation (S600), the apparatus 20′, as in FIG.

2, may determine that, when a first comparison signal Scom1 is at a low level (logic “0”), a voltage differentiation value d(m)V/dT(m) is within a range of a voltage reference (see S652), for example, and when a second comparison signal Scom2 is not at a low level (logic “0”) but at a high level (logic “1”), a temperature error value ΔT is out of a range of a temperature reference (see S653).

In this case, states of the first to nth battery cells BC (BC1 to BCn) included in the tray 50 may be determined as a defective state, and therefore, an output signal Sout having a high level may be output.

Next, regarding condition 3, in the defect determination operation (S600), the apparatus 20′, as in FIG. 2, may determine that a voltage differentiation value d(m)V/dT(m) is out of a range of a voltage reference when a first comparison signal Scom1 is not at a low level (logic “0”) but at a high level (logic “1”) (S652).

In this case, it can be recognized that there is possibility of defectiveness regardless of a state of a second comparison signal Scom2, and recharging may be performed for a plurality of battery cells included in the tray (see S654).

After recharging is performed by a charger (100 of FIG. 2) for the first to n^{th} battery cells BC (BC1 to BCn) included in the tray 50, a defective state or a normal state of the plurality of battery cells included in the tray may be determined again based on the first comparison signal Scom1 and the second comparison signal Scom2.

Next, condition 4, condition 5 and condition 6 will be explained.

After recharging, condition 4 will be explained, in the defect determination operation (S600), the apparatus 20′, as in FIG. 2, may determine that, when a first comparison signal Scom1 is at a low level (logic “0”), a voltage differentiation value d(m)V/dT(m) is within a range of a voltage reference (see S655), and when a second comparison signal Scom2 is at a low level (logic “0”), a temperature error value ΔT is within a range of a temperature reference (see S656).

In this case, states of the first to nth battery cells BC (BC1 to BCn) included in the tray 50 may be determined as a normal state, and therefore, an output signal Sout having a low level may be output.

Next, after recharging, regarding condition 5, in the defect determination operation (S600), the apparatus 20′, as in FIG. 2, may determine that, when a first comparison signal Scom1 is at a low level (logic “0”), a voltage differentiation value d(m)V/dT(m) is within a range of a voltage reference (see S655), for example, and when a second comparison signal Scom2 is at a high level (logic “1”), a temperature error value ΔT is out of a range of a temperature reference (see S656).

In this case, states of the first to nth battery cells BC (BC1 to BCn) included in the tray 50 may be determined as a defective state, and therefore, an output signal Sout having a high level may be output.

Next, after recharging, referring to condition 6, in the defect determination operation (S600), the apparatus 20′, as in FIG. 2, may determine a defective state regardless of a state of the second comparison signal Scom2, for example, when a first comparison signal Scom1 is at a high level (logic “1”) (see S655), and may output an output signal Sout of a high level.

Contents described above are merely examples of applying the principles of the disclosure of this patent document, and other configurations may be further included without departing from the scope of the disclosure of this patent document.

According to an aspect of the disclosure of this patent document, not only a voltage differentiation value, but also a temperature error value obtained based on a voltage profile and a temperature profile for each of a plurality of battery cells included in a tray, may be used to provide an effect of more accurately inspecting internal damage or defects of the battery cells, such as internal short or the like due to folding or damage of a separator, in a previous procedure prior to manufacturing of a battery module.

Various advantages and effects of the disclosure of this patent document are not limited to the above-described contents, and other technical effects not mentioned can be more easily understood in the process of explaining the specific implementation of the disclosure of this patent document from the description below.

Only specific examples of implementations of certain embodiments may be described. Variations, improvements and enhancements of the disclosed embodiments and other embodiments may be made based on the disclosure of this patent document.

What is claimed is:

1. An apparatus for inspecting a battery defect based on a charging profile, comprising:
a voltage detector generating a voltage profile including a detection voltage, detected during charging for a plurality of battery cells included in a tray;
a temperature detector generating a temperature profile including a detection temperature detected during the charging;
a first processing unit obtaining a voltage differentiation value based on the voltage profile;
a second processing unit obtaining a temperature error value based on the temperature profile; and
a defect determination unit determining a defective state or a normal state for the plurality of battery cells included in the tray, based on the voltage differentiation value and the temperature error value.

2. The apparatus of claim 1, further comprising a charger performing the charging for the plurality of battery cells included in the tray.

3. The apparatus of claim 2, wherein the first processing unit comprises any one of:
a first differentiation value generating unit generating a first voltage differentiation value, based on the voltage profile for each of the plurality of battery cells included in the tray; or
a second differentiation value generating unit generating a second voltage differentiation value, based on the voltage profile for each of the plurality of battery cells included in the tray.

4. The apparatus of claim 2, wherein the second processing unit comprises:
a temperature median value generating unit generating a temperature median value of the plurality of battery cells at a preset time, based on the temperature profile for each of the plurality of battery cells included in the tray; and
a temperature comparison unit generating a temperature error value using a temperature value of each of the plurality of battery cells and the temperature median value therebetween.

5. The apparatus of claim 2, wherein the defect determination unit comprises:
a first comparison unit comparing whether the voltage differentiation value is within a range of a voltage reference and outputting a first comparison signal;
a second comparison unit comparing whether the temperature error value is within a range of a temperature reference and outputting a second comparison signal; and
a state determination unit determining a defective state or a normal state for the plurality of battery cells included in the tray, based on the first comparison signal and the second comparison signal.

6. The apparatus of claim 5, wherein the defect determination unit determines states of the plurality of battery cells included in the tray as a normal state, when the voltage differentiation value is within the range of the voltage reference and the temperature error value is within the range of the temperature reference.

7. The apparatus of claim 5, wherein the defect determination unit determines states of the plurality of battery cells included in the tray as a defective state, when the voltage differentiation value is within the range of the voltage reference and the temperature error value is out of the range of the temperature reference.

8. The apparatus of claim 5, wherein the defect determination unit determines again a defective state or a normal state for the plurality of battery cells included in the tray, based on the first comparison signal and the second comparison signal after recharging through the charger, when the voltage differentiation value is out of the range of the voltage reference.

9. The apparatus of claim 8, wherein the defect determination unit determines, after recharging through the charger, states of the plurality of battery cells included in the tray a normal as state, when the voltage differentiation value is within the range of the voltage reference and the temperature error value is within the range of the temperature reference.

10. The apparatus of claim 8, wherein the defect determination unit determines, after recharging through the charger, states of the plurality of battery cells included in the tray as a defective state, when the voltage differentiation value is within the range of the voltage reference and the temperature error value is out of the range of the temperature reference.

11. The apparatus of claim 8, wherein the defect determination unit determines, after recharging through the charger, states of the plurality of battery cells included in the tray as a defective state, when the voltage differentiation value is out of the range of the voltage reference.

12. A method for inspecting a battery defect based on a charging profile, comprising:
a charging operation of performing charging of a plurality of battery cells included in a tray;
a voltage detection operation of generating a voltage profile including a detection voltage, detected during the charging for the plurality of battery cells included in the tray;
a temperature detection operation of generating a temperature profile including a detection temperature detected during the charging;
a first processing operation of obtaining a voltage differentiation value based on the voltage profile;
a second processing operation of obtaining a temperature error value based on the temperature profile; and
a defect determination operation of determining a defective state or a normal state of the plurality of battery cells included in the tray, based on the voltage differentiation value and the temperature error value.

13. The method of claim 12, wherein the first processing operation comprises any one of:
a first differentiation value generation operation of generating a first voltage differentiation value based on the voltage profile for each of the plurality of battery cells included in the tray; or
a second differentiation value generation operation of generating a second voltage differentiation value based on the voltage profile for each of the plurality of battery cells included in the tray.

14. The method of claim 12, wherein the second processing operation comprises:
a temperature comparison operation of generating a temperature error value between a temperature median value of the plurality of battery cells and a temperature value of each of the plurality of battery cells at a preset time, based on the temperature profile for each of the plurality of battery cells included in the tray.

15. The method of claim 12, wherein the defect determination operation comprises:
a first comparison operation of comparing whether the voltage differentiation value is within a range of a voltage reference and outputting a first comparison signal;
a second comparison operation of comparing whether the temperature error value is within a range of a temperature reference and outputting a second comparison signal; and
a state determination operation of determining a defective state or a normal state for the plurality of battery cells included in the tray, based on the first comparison signal and the second comparison signal.

16. The method of claim 15, wherein the defect determination operation determines:
states of the plurality of battery cells included in the tray as a normal state, when the voltage differentiation value is within the range of the voltage reference and the temperature error value is within the range of the temperature reference, and
states of the plurality of battery cells included in the tray as a defective state, when the voltage differentiation value is within the range of the voltage reference and the temperature error value is out of the range of the temperature reference.

17. The method of claim 15, wherein the defect determination operation determines again a defective state or a normal state for the plurality of battery cells included in the tray, based on the first comparison signal and the second comparison signal after recharging the plurality of battery cells included in the tray, when the voltage differentiation value is out of the range of the voltage reference.

18. The method of claim 17, wherein the defect determination operation determines, after recharging through a charger:
states of the plurality of battery cells included in the tray as a normal state, when the voltage differentiation value is within the range of the voltage reference and the temperature error value is within the range of the temperature reference; and
states of the plurality of battery cells included in the tray as a defective state, when the voltage differentiation value is within the range of the voltage reference and the temperature error value is out of the range of the temperature reference.

19. The method of claim 17, wherein the defect determination operation determines, after recharging through a charger, states of the plurality of battery cells included in the tray as a defective state, when the voltage differentiation value is out of the range of the voltage reference.
